(19) United States
(12) Patent Application Publication
(10) Pub. No.: US 2024/0079989 A1
(43) Pub. Date: Mar. 7, 2024

(54) INTEGRATED PHOTOVOLTAIC ROOF ELEMENT

(71) Applicant: EXASUN B.V., The Hague (NL)

(72) Inventors: Michiel Herman MENSINK, The Hague (NL); Jan-jaap Eduard VAN OS, The Hague (NL)

(73) Assignee: EXASUN B.V., The Hague (NL)

(21) Appl. No.: 18/270,108

(22) PCT Filed: Dec. 22, 2021
(86) PCT No.: PCT/NL2021/050780

§ 371 Date: Jun. 28, 2023

(30) Foreign Application Priority Data
Dec. 31, 2020 (NL) 2027258

(51) Int. Cl. H02S 20/25

(52) U.S. Cl. CPC H02S 20/25

(57) ABSTRACT

The present invention relates to a photovoltaic assembly for incorporation into a tiled roof, the assembly comprising: (i) a photovoltaic panel comprising a transparent top sheet and a backsheet, and one or more photovoltaic cells positioned between the top and backsheet; (ii) two side elongate elements extending vertically along the sides of the panel; (iii) an upper elongate sealing element extending in a horizontal direction, and attached to an upper end of the side elongate frame elements and above the photovoltaic panel, (iv) a lower elongate sealing element extending horizontal direction and attached to the panel in horizontal direction on the underside of the panel; wherein at least one of the side elongate frame element extends laterally to form a flashing portion that substantially interlinks with the underside of a laterally positioned roofing component.

### FIELD OF THE INVENTION

The present invention relates to the field of integrated solar-panel roofing systems, in particular photovoltaic systems for tiled surfaces, such as roofs. More specifically the present invention provides a building-integrated solar-panel roof element comprising one or more photovoltaic panels for integration into pitched roofs, as well as such a building-integrated roof elements fitted with a photovoltaic panel, and an array of these solar energy roof elements mounted on a pitched roof.

### BACKGROUND OF THE INVENTION

Photovoltaic electricity generation has received increasing attention as a renewable energy source. Therefore, photovoltaic installations on commercial and residential roofs have increasingly become popular in recent years. However, the majority of existing domestic photovoltaic installations to date consists of non-integrated systems, which accommodate the shape and size of the photovoltaic cells rather than those of the existing roofs and façades Such systems generally comprise an array of photovoltaic or solar thermal modules attached to a separate support structure, which is usually affixed on top of an existing roof covering or façade.

These structures are however comparatively heavy, and require installing and maintenance activities. Also, structural upgrades to the building may be required to the additional static loads. Also, such structures may be subject to potential wind damage, may generate undesired noise, cold spots, or waterproofing issues such as leakages where the support structures are anchored.

Accordingly, there is a need for integrating photovoltaic modules, in particular one where such modules interface with current roof coverings such as tiles, slates and metal roofing, and wherein the photovoltaic or optionally also thermal solar panels constitute structural elements of a roof.

Many different solutions have been proposed, and usually comprise photovoltaic elements in some sort of frame or cradle or frame assembled around the photovoltaic elements in much the same manner as a picture frame. These assemblies are then attached to the roof by means of brackets.

Examples include US20060196128A1, which discloses a four-sided frame unit designed to be moulded from recycled plastic; US20060042680A1, which discloses a mounting for solar panels with a plastic frame around a photovoltaic laminate and a complex sealing arrangement, mounted on a polymer substrate; WO2008052816, which discloses an integrated modular photovoltaic element designed to match with classic tiles, the element comprising a lower hollow structural part of plastic material and an upper convex element of light-transparent material; U.S. Pat. Nos. 7,012,188, 4,336,413, GB2548983 and U.S. Ser. No. 10/734,939 disclose framing systems for solar panels comprising interconnected frame elements joined with a capping element over facing edges, or elements structured to form frame-like structures. Although some of these publications also disclose polymeric sealing strips in addition to the framing parts, these arrangements all make use of substantial mounting frames, which increases the weight and thickness of the installation, and makes them only suitable for a particular type of roofing. Also, the frames and inserted solar panels are likely prone to wind shear, which may cause damage under adverse weather conditions, and eventual leakage due to torsion. Yet further, frames and supporting structures thereof will cast shadow on the module during its typical time of operation. Moreover, upstanding frame elements typically lead to accumulation of dirt, eventually leading to a reduced lighting of the solar cell, and corrosion of the frame parts,

EP 2348542 discloses a different solar panel for use with flat roof tiles. The disclosed panel however lacks the upper elongate member for sealing to the lower part of a previous roof tile, thereby allowing direct contact between the solar panel and any tiles above, leading to damage under wind shear conditions, and potentially water creep under wind pressure into the roof construction. Hence, this panel cannot be used with different roof tile structures.

### SUMMARY OF THE INVENTION

The present invention provides a building-integrated modular solar-panel roof element, in particular a photovoltaic roof element, comprising the panel that can be integrated in a pitched roof, as well as such a building-integrated roof element fitted with a photovoltaic panel, and an array of these solar energy roof elements mounted on a pitched roof. The panels according to the invention in particular make use of the strength and resilience of photovoltaic panels, in particular those prepared as a sandwich construction comprising both top and backsheet prepared from glass, which in principle has a similar, if not superior resistance to weathering conditions as ceramic roof tiles, and does not necessitate the use of a dedicated frame.

Also, the roof element according to the invention has the benefit of being much lighter than those disclosed in the prior art that make use of rigid frames, and due to the generally flat surface area allows adaptation to various different roof tiles or shingles, simply by adapting the size and shape of the upper and lower polymeric weathering strips.

The invention also provides a building integrated system roof element which is in principle compatible to any kind of roofing tiles. Yet further, the system can be easily dismounted but also mounted back, without disrupting the other elements making up the complete covering of the roof; and is weather- and waterproof; and can be made to any convenient size which combines ease of handling with reduced installation costs.

According to a main aspect, the invention relates to a photovoltaic assembly for incorporation into a tiled roof, the assembly comprising:
(i) a photovoltaic panel comprising a transparent top sheet and a backsheet, and one or more photovoltaic positioned between the top and backsheet;
(ii) two side elongate elements extending vertically along the sides of the panel;
(iii) an upper elongate sealing element extending in a horizontal direction, and attached to an upper end of the side elongate elements and above the photovoltaic panel,
(iv) a lower elongate sealing element extending horizontal direction and attached to the panel in horizontal direction on the underside of the panel; wherein at least one of the side elongate element extends laterally to form a flashing portion that substantially interlinks with the underside of a laterally positioned roofing component. The frameless photovoltaic module according to the invention has the benefit of minimalizing the use of mounting systems that might shade the cells in the module, such as conventional mounting frames from traditional rooftop mounting systems, for example. Also, the clearance around the edges of the module and the cells in the module is increased and can be chosen such as to account for the module-intruding shading and the shading caused by the height of the mounting elements as the sun moves throughout the day and season.

Yet further, the absence of exposed frame parts reduces shadowing under shallow angles, and collection of dirt that may impact incandescence and durability, in particular on lowly pitched roof surfaces.

In the present assembly, each photovoltaic roof element is arranged so that one, or a plurality of the elements can be integrated in a pitched roof with the side walls of adjacent side-by-side elements in inter-engaging relationship and with the top and bottom edges respectively of adjacent lower and upper elements overlapping and inter-engaging with one another, the elements can be mounted on the roof by means of fitting brackets engaging with the side elements of the elements, to form a generally planar solar panel array.

Another aspect of the invention is an array of integrated photovoltaic roof elements as set out above and mounted on a pitched roof.

Yet another aspect of the invention resides in a panel comprising photovoltaic cells for mounting with the roof construction. Yet another aspect of the invention resides in the side elements for affixing photovoltaic cells for mounting with the side elements.

The invention is suitable for sloped rooves, but facade linings are also possible. The incline of the line of slope should be at least so great that the water which hits the corresponding part of the building envelope cannot penetrate, but runs off exclusively to the outside.

### BRIEF DESCRIPTION OF THE DRAWINGS

The invention will be further described by way of example with reference to the accompanying schematic and exemplary drawings, in which:

FIG. 1 is a perspective view from above a preferred assembly (1).

FIG. 2 is a perspective view showing the underside of a preferred assembly.

FIG. 3 is a perspective view showing a preferred assembly from an about 45° angle.

FIG. 4 is a side perspective view from the side of an assembly.

FIG. 5 is a cut-away perspective view from the side of two preferred assemblies connecting centrally to one another, and two roof tiles to the left and right.

FIG. 6 is a perspective enlarged view of connections B, C and D of FIG. 5.

FIG. 7 shows side (A) and perspective views (B) and (C) of preferred embodiments of the side elements.

FIG. 8 is a cut-away perspective view from the side showing three different preferred assemblies according to the invention

FIG. 9 E to G are detailed enlargements of the situations of FIGS. 8 E to G.

FIG. 10 is a perspective view of a preferred assembly according to the invention.

FIG. 11 is a perspective view showing a preferred retainer bracket or element.

FIG. 12 is a side view showing a preferred wind hook (16).

FIG. 13 is a perspective view showing a preferred photovoltaic panel according to the invention.

FIG. 14 is a perspective view of the preferred photovoltaic panel, showing conductors ribbons 23 inside the panel, and outlining the entry opening 21 for the junction box 22.

### DETAILED DESCRIPTION

Unless stated otherwise, all percentages, parts, ratios, etc., are by weight. When an amount, concentration, or other value or parameter is given as either a range, preferred range or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

When the term “about” is used in describing a value or an end-point of a range, the disclosure should be understood to include the specific value or end-point referred to.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. The transitional phrase “consisting essentially of limits the scope of a claim to the specified materials or steps and those that do not materially affect the basic and novel characteristic(s) of the claimed invention. Where applicants have defined an invention or a portion thereof with an open-ended term such as “comprising,” it should be readily understood that unless otherwise stated the description should be interpreted to also describe such an invention using the term “consisting essentially of”.

Use of “a” or “an” are employed to describe elements and components of the invention. This is merely for convenience and to give a general sense of the invention. This description should be read to include one or at least one and the singular also includes the plural unless it is obvious that it is meant otherwise.

In describing certain polymers it should be understood that sometimes applicants are referring to the polymers by the monomers used to produce them or the amounts of the monomers used to produce the polymers. While such a description may not include the specific nomenclature used to describe the final polymer or may not contain product-by-process terminology, any such reference to monomers and amounts should be interpreted to mean that the polymer comprises those monomers (i.e. copolymerized units of those monomers) or that amount of the monomers, and the corresponding polymers and compositions thereof.

In describing and/or claiming this invention, the term “copolymer” is used to refer to polymers formed by copolymerization of two or more monomers. Such copolymers include dipolymers, terpolymers or higher order copolymers.

Typical photovoltaic elements according to the invention preferably have a layer sequence as follows: a top sheet comprising a textured front sheet and a pigmented layer adjacent and adhered thereto, an encapsulant polymer layer, a photovoltaic cell, an encapsulant layer and a back sheet.

The term “first layer” and “second layer” refers to any layer of the module that is present in the direction of the incandescent light. The layer may be the layer that is directly in contact with the glass or front sheet, as the pigmented coating layer, or may be an intermediate layer. In this respect, the next layer refers to a layer further down in the direction of the incandescent light. The layers may be directly adjacent to each other, or may be separated by further intermediate layers.

Photovoltaic Panel

Any suitable type of photovoltaic panel can be fitted in the assembly according to the invention. Usually the photovoltaic panel comprises a glass or transparent or translucent outside panel supporting on its rear face a photovoltaic material or cells. Many photovoltaic panels use wafer thin crystalline silicon cells, or thin films based on cadmium telluride or silicon, for example. Generally, any of the commercially available photovoltaic panels can be used. Electrical connections to the photovoltaic elements may be made by conductors extending for example from one or two holes in the underside of the panel.

The encapsulated photovoltaic element includes a top layer material at its top surface, i.e. facing the direction of the incandescent light, and a bottom or backing layer material at its bottom surface. The top layer is comprised of a textured top sheet, with the texture pointing inwardly, and pigmented coating layer adhered to the textured side of the top sheet.

Top Sheet

The top sheet may comprise a layer material may, for example, provide environmental protection to the underlying photovoltaic cells, and any other underlying layers. Examples of suitable materials for the top layer material include any suitable transparent material, e.g. polymeric materials, in particular epoxy, (meth)acrylate or polycarbonate materials, or fluoropolymers, for example ETFE, PFE, FEP, PCTFE or PVDF. The top layer material however preferably is a transparent glass or ceramic sheet. Thin hardened and highly transmissive glass or glass ceramic sheets are particularly preferred. Such glass sheets advantageously are provided with a micro-texture at one side, which can then be coated with the pigmented layer. Such panels are particularly long-lived and best withstand weather effects. To produce photovoltaic energy, the panel is at least in part equipped with photovoltaic cells. These preferably have a square or rectangular shape and are housed in the photovoltaic cell region of the panel. They can completely cover the surface. But versions of arrangements are also possible in which the photovoltaic cells have a certain mutual distance so that some of the sunlight is passed through the panel. The photovoltaic cell region is typically square and has a certain distance to the edge of the panel. The edge region which surrounds the photovoltaic cell region is dimensioned according to the required overlapping of the installed panels, for example a few centimetres.

The top sheet may further include at least one antireflection coating, for example as the top layer material, or disposed between the top layer material and the photovoltaic cells.

Preferably the top sheet, facing the incoming radiation has a thickness of between 1.5 and 4 mm. Preferred are glass sheets, which may for example be float glass or roll glass having a texture structure applied at least to one side of the sheet. The glass sheet may optionally be thermally treated. The glass sheet may comprise sodium free glass, for example alumina silicate or borosilicate glass. For large volume production it is preferred to use a soda lime glass or borosilicate glass. Preferably the top sheet, facing the incoming radiation has a thickness of between 1.5 and 4 mm. Preferred are glass sheets, which may for example be float glass or roll glass having a texture structure applied at least to one side of the sheet. The glass sheet may optionally be thermally treated. The glass sheet may comprise sodium free glass, for example alumina silicate or borosilicate glass. For large volume production it is preferred to use a soda lime glass or borosilicate glass. The soda lime glass may comprise between 67-75% by weight SiO₂, between 10-20% by weight; Na₂O, between 5-15% by weight CaO, between 0-7% by weight MgO, between 0-5% by weight Al₂O₃; between 0-5% by weight K₂O, between 0-1.5% by weight Li₂O and between 0-1%, by weight BaO. Such a glass will suitably have a transparency of higher than 90%. Suitably the glass has been subjected to a thermally toughening treatment after the texture has been applied.

The surface of the glass layer, especially the surface not facing the pigmented coating layer and facing the incoming radiation may be preferably coated with a suitable anti-reflection layer. The anti-reflective layer will limit the radiation which reflects at the glass surface. Limiting this reflection will increase the radiation passing the glass element which will as a result enhance the efficiency of the glass element to transmit radiation. Preferably the coating is applied to one glass layer, namely the glass layer which will in use face the incoming radiation, i.e. sunlight. A suitable anti-reflection coating will comprise of a layer of porous silica. The porous silica may be applied by a sol-gel process as for example described in U.S. Pat. No. 7,767,253. The porous silica may comprise of solid silica particles present in a silica-based binder. Processes to prepare glass layers having an anti-reflective coating are for example described in WO-A-2004104113 and WO-A-2010100285.

Preferably, the photovoltaic element may comprise as follows: i.a light transmissive, coloured top sheet comprising a. a textured transparent front cover sheet; and b. a pigmented top coating layer disposed on the backside of the top sheet with respect to the direction of the incandescent light; ii. a first encapsulant layer iii. one or more photovoltaic cells, each comprising at least one photovoltaically active surface and comprising two electrically-conductive electrode layers with a photovoltaic material disposed between them; iv. a second encapsulant layer, and v. a back cover sheet.

The side facing the optional pigmented coating layer is provided with a micro-texture. The actual geometry of the texture is not important, as long as it allowed the top sheet when coated to give the desired birefringent colour appearance. Typical textures comprise dimples, pyramidal structures, grids and the like, such as for instance disclosed in EP-A-1774372 or EP-A-2850664. The concentration of the pigments in the top sheet pigmented layer may depend on the chosen colour effect of the module. Some pigments or pigment combinations are more effective and will require a lower concentration in the layer and some compounds will require a higher concentration because they are less efficient in the desired colour tone.

The encapsulated photovoltaic element may comprise other layers interspersed between the top layer material and the bottom layer material. For example, the encapsulated photovoltaic element can include structural elements, such as a reinforcing layer of glass, metal or polymer fibres, or a rigid film; adhesive and encapsulant layers, such as EVA to adhere other layers together; mounting structures, such as clips, holes, or tabs; and one or more optionally connectorized electrical cables for electrically interconnecting the photovoltaic cell(s) of the encapsulated photovoltaic element with an electrical system.

A photovoltaic module or element according to the invention may be prepared by stacking the different layers of the top sheet and the photovoltaic cell, additional encapsulant layer or layers and a backsheet layer and subjecting the formed stack to a lamination process step.

Prefearbly, the method further comprises c) providing a stack comprising the light transmissive coloured top sheet obtained; a first encapsulant material; one or more photovoltaic cells comprising at least one photovoltaically active surface and comprising two electrically-conductive electrode layers with a photovoltaic material disposed between them; a second encapsulant material, and ii.) subjecting the stack obtained in i.) to a suitable pressure and temperature, to obtain a photovoltaic element.

To carry out encapsulation, a laminating encapsulant film, and a top sheet, for instance a coated glass sheet, for example a low-iron soda-lime glass, are positioned over the photovoltaic module having integrated serial connection, and a second encapsulant sheet and a backsheet are laid down and subsequently laminated in a thermal curing step. Typical lamination temperatures are in the range from 50 to 200° C. The lamination temperature may be between 115 and 175° C. and wherein the environment of the stack preferably has a pressure of less than 30 mBar, more preferably less than 1 mBar. In this process the stack is preferably present in a vacuum laminator and pressure bonded under conversion heating at a temperature in the range of from of 115 to 175° C., preferably 140 to 165° C., most preferably from 145 to 155° C. The laminate is preferably also subjected to degassing. The compression lamination pressure preferably is in the range of from of 0.1 to 1.5 kg/cm². The lamination time typically is in the range of from 5 to 25 minutes. This heating enables for example the ethylene-vinyl acetate copolymer contained in the polymer sheet according to the invention and in the encapsulant layer to crosslink, whereby the photovoltaic cell, the polymer sheet and the encapsulant layer are strongly adhered to seal the photovoltaic cell and obtain the photovoltaic module according to the invention. Where “dummy” modules are desired with the same appearance the above process is repeated, however omitting the photovoltaic cells.

Encapsulated photovoltaic element include a textured top protective layer comprising coating layer; e.g., a coated glass sheet; a first encapsulant layer, preferably comprising EVA, functionalized EVA, crosslinked EVA, silicone, thermoplastic polyurethane, maleic acid-modified polyolefin, ionomer, or ethylene/(meth)acrylic acid copolymer); a layer of electrically-interconnected photovoltaic cells; a optionally pigmented back encapsulant layer; and a backing sheet layer, such as glass, aluminium, PVDF, PVF, or PET.

The present invention can be practiced using any of a number of types of architectural substrates. For example, in certain embodiments of the invention, the top surface of the roofing substrate is polymeric (e.g., a polymeric material, or a polymeric coating on a metallic material).

In other embodiments of the invention, the back surface of the element may be metallic.

In other embodiments of the invention, the back surface of the element is coated with roofing granules, such as for instance a bituminous material coated with roofing granules. In other embodiments of the invention, the back surface of the roofing substrate is bituminous such as an uncoated bituminous roofing substrate.

The pigmented and thus coloured coating layer is prefearbly designed to resemble a natural material such ceramics or stone, or other manmade materials such as ceramic or concrete, or to blend in with the environment, e.g. when used for noise barrier along roads or highways.

Applicants found that the combination of the textured top sheet and the presence of plate-like pigments results in a birefringent colour effect, at a relatively low adsorption rate. In particular, the top sheet including the coloured coating layer forms a birefringent multilayer optical film having an angularly-dependent appearance. The colour-shift effect of layer can be further modified by adjusting the reflectance or absorbance behaviour of the layers beneath the birefringent optical film.

Pigments

Suitable pigments may comprise pearlescent pigments, nacreous pigments, metal flake pigments or encapsulated metal flake pigments. In particular, light-interference platelet pigments are known to give rise to various optical effects when incorporated in coatings, including opalescence or pearlescence. Particularly preferred are multilayer interference pigments consisting of a carrier material coated with alternating layers of metal oxides of high and low refractive index, the layer(s) of the metal oxide of low refractive index being optically inactive. Preferably, the carrier material is mica, another phyllosilicate, glass flakes, or platelet-form silicon dioxide. Preferred are also pigments that comprise an additional coating with complex salt pigments, especially cyanoferrate complexes, for example Prussian Blue and Turnbull's Blue. The pigment may also be coated with organic dyes and, in particular, with phthalocyanine or metal phthalocyanine and/or indanthrene dyes. This is done by preparing a suspension of the pigment in a solution of the dye and then bringing this suspension together with a solvent in which the dye is of low or zero solubility.

The thickness of the interlayers of metal oxides of low refractive index within a metal oxide layer of high refractive index is from 1 to 20 nm, preferably from 2 to 10 nm. Within this range, a metal oxide layer of low refractive index, for example silicon dioxide, is optically inactive, which is an essential feature of the present invention.

The thickness of the layers of metal oxides of high refractive index is between 20 and 350 nm, preferably between 40 and 260 nm. Since the interlayers of low-refractive-index metal oxides greatly increase the mechanical stability of the layers of high-refractive-index metal oxides, it is also possible to prepare thicker layers of adequate stability. In practice, however, layer thicknesses of only up to 260 nm are employed, which in the case of a titanium dioxide-mica pigment would correspond to a 3^{rd} order green aspect.

The inherent colour as well as the interference colour of the interference pigments according to the invention can be varied within a wide range and optimized with a view to the particular application. Thus, for example, the inherent colour can be selectively established by choosing a coloured substrate and/or by using one or more coloured metal oxides as components of the film covering the carrier. The present invention permits to prepare all kinds of colours and appearances, such as green, gold, terracotta, blue, violet, red or orange. just to name a few colours.

The number and thickness of the interlayers is dependent on the total layer thickness of the metal oxide layer of high refractive index. The interlayer is preferably arranged such that the layer thickness of the metal oxide layers of high refractive index corresponds to the optical thickness, or to an integral multiple of this optical thickness, which is necessary for the respective interference colour.

The metal oxide of high refractive index can be an oxide or mixtures of oxides with or without absorbing properties, such as TiO₂, ZrO₂, Fe₂O₃, Fe₃O₄, Cr₂O₃ or ZnO, or a compound of high refractive index such as, for example, iron titanates, iron oxide hydrates and titanium suboxides, or mixtures and/or mixed phases of these compounds with one another or with other metal oxides.

The metal oxide of low refractive index may be selected from SiO₂, Al₂O₃, AlOOH, B₂O₃ or a mixture thereof and can likewise have absorbing or non-absorbing properties. If desired, the oxide layer of low refractive index may include alkali metal oxides and alkaline earth metal oxides as constituents.

Examples of light-interference platelet pigments that can be employed in the pigmented layer of the present invention include light-interference pearlescent pigment based on mica covered with a thin layer of titanium dioxide and/or iron oxide; platelet crystal effect pigment based upon Al₂O₃ platelets coated with metal oxides, multi colour effect pigments based on SiO₂ platelets coated with metal oxides; ultra-interference pigments based on TiO₂ and mica; and mirrorized silica pigments. In one embodiment of the invention, a layer having a metallic or light-interference effect is disposed on a layer having a white reflective pigment (e.g., TiO₂ or ZnO₂). This can increase the efficiency of the metallic/light-interference pigments by increasing scattering from the background. In some embodiments, the one or more colorants can themselves have a multilayer structure, such that thin film interference effects give rise to metallic appearance effects or angular metametrism.

Furthermore, it is of course also possible to incorporate small inorganic pigment particles having a particle size of less than 100 nm and in particular 5 to 50 nm into one or, if desired, more of the films. Suitable light-interference platelet pigments may have an equivalent diameter distribution, according to which 90% of the particles are in the range from 2 to 40 μm, preferably from 5 to 40 μm in particular from 3 to 35 μm, very particularly preferably from 5 to 30 μm. In addition to the equivalent diameter distribution, the thickness distribution of the platelets also plays a role. Thus, suitable base substrates preferably have a thickness distribution, according to which 90% of the particles are in the range from 100 to 3500 nm, preferably 200 to 2600 nm, in particular 250 to 2200 nm.

Preferably, the aspect ratio (aspect ratio: diameter/thickness ratio) of the platelets is 5-200, especially 7-150, and most preferably 10-100.

In some embodiments of the invention, the pigmented layer may include one or more additional or alternative pigments, including but not limited to ultramarine blue, ultramarine purple, cobalt chromite blue, cobalt aluminium blue, chrome titanate, nickel titanate, cadmium sulphide yellow, cadmium sulphide yellow, cadmium sulfoselenide orange, and organic pigments such as perylene black, phthalo blue, phthalo green, quinacridone red, diarylide yellow, azo red, and dioxazine purple. Additional pigments may comprise iron oxide pigments, titanium oxide pigments, composite oxide system pigments, titanium oxide-coated mica pigments, iron oxide-coated mica pigments, scaly aluminium pigments, zinc oxide pigments, copper, nickel, cobalt or iron phthalocyanine pigment, non-metallic phthalocyanine pigment, chlorinated phthalocyanine pigment, chlorinated-brominated phthalocyanine pigment, brominated phthalocyanine pigment, anthraquinone, quinacridone system pigment, diketo-pyrrolipyrrole system pigment, perylene system pigment, monoazo system pigment, diazo system pigment, condensed azo system pigment, metal complex system pigment, quinaphthalone system pigment, Indanthrene Blue pigment, dioxadene violet pigment, anthraquinone pigment, metal complex pigment, benzimidazolone system pigment, and the like.

The pigments are added to the coating composition that forms the pigmented layer according to the invention after application in a concentration that is generally suitable for the colour depth and effect to be achieved. Preferably, the pigments according to the invention are present in an amount of from. 0.1 to 80% by weight based on the coating composition, preferably of from 1 to 40%, yet more preferably of from 2 to 15% by weight.

In certain embodiments of the invention, the coloured pigmented layer may also include a coloured, infrared-reflective pigment, for example comprising a solid solution including iron oxide; or a near infrared-reflecting composite pigments. Composite pigments are composed of a near-infrared non-absorbing colorant of a chromatic or black colour and a white pigment coated with the near infrared-absorbing colorant. Near-infrared non-absorbing colorants that can be used in the present invention include organic pigments such as organic pigments including azo, anthraquinone, phthalocyanine, perinone/perylene, indigo/thioindigo, dioxazine, quinacridone, isoindolinone, isoindoline, diketopyrrolopyrrole, azomethine, and azomethine-azo functional groups, and include chromium green-black, chromium iron oxide, zinc iron chromite, iron titanium brown spinel, and chrome antimony titanium.

Preferred black organic pigments include organic pigments having azo, azomethine, and perylene functional groups. Coloured, infrared-reflective pigments can be present, for example, at a level in the range of about 0.1% by weight to about 10 percent by weight of the pigmented layer composition. Preferably, such a coating composition forms a layer having sufficient thickness to provide good colour effect, but at sufficient transparency, such as a thickness of from about 5 μm to about 150 μm.

Applicants found that in spite of the relatively high pigmentation, transmission was not significantly reduced. For instance blue or green coloured photovoltaic modules only showed a reduction in efficiency sa compared to unpigmented muddles of from 5 to 8%, whereas even for a terracotta pigmentation, an efficiency reduction of only about 20% was found. This compares very favourably to pigmented solid glass front sheets, and to encapsulants with pigments therein. Without wishing to be bound to any particular theory, it is believed that the combination of the interference pigments and the texture at the inside of the top sheet form a birefringent composite sheet, which scatters light to the eye of the beholder in a more prominent way that traditional pigmented top layers, while at the same time allowing transmission of sufficient light to maintain a high efficiency.

Advantageously, the present photovoltaic modules can be prepared in almost any colour tone, allowing for a very wide applicability ranging from the apparition close to traditional roof tiles, to noise barriers, to colour tones that blend in with the environment, e.g. forest or dunes; and colours chosen to enhance architectural features.

Since not all surfaces of a building or other structures need to, or are suitable for providing photovoltaic electricity, the present invention also pertains to panels that are complementary to the elements according to the invention, but entirely or in part void of photovoltaic cells. Such panels accordingly comprise a light transmissive, coloured top sheet comprising a. a textured transparent front cover sheet; and b. a pigmented top coating layer disposed on the inside of the top sheet with respect to the direction of the incandescent light; a first encapsulant layer. a second encapsulant layer, and a back cover sheet. Such “dummy” panels may also be used to cut or shape for suitable roof coverage, e.g. at corners.

The photovoltaic cell may be monofacial or bifacial. The photovoltaic cells can be based on any desirable photovoltaic material system, such as monocrystalline silicon; polycrystalline silicon; amorphous silicon; Ill-V materials such as indium gallium nitride; II-VI materials such as cadmium telluride; and more complex chalcogenides (group VI) and pnicogenides (group V) such as copper indium diselenide or CIGS. For example, one type of suitable photovoltaic cell includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Thin-film amorphous silicon materials can also be used, which can be provided in flexible forms. Another type of suitable photovoltaic cell is an indium phosphide-based thermo-photovoltaic cell, which has high energy conversion efficiency in the near-infrared region of the solar spectrum. Thin film photovoltaic materials and flexible photovoltaic materials can be used in the construction of encapsulated photovoltaic elements for use in the present invention. In one embodiment of the invention, the encapsulated photovoltaic element includes a monocrystalline silicon photovoltaic cell or a polycrystalline silicon photovoltaic cell. The photovoltaic cells can be interconnected to provide a single set of electrical contacts for a module. The module according to the invention may also be combined with wafer-based photovoltaic cells based on monocrystalline silicon (c-Si), poly- or multi-crystalline silicon (poly-Si or mc-Si) and ribbon silicon. Preferably the module comprising wafer-based photovoltaic cells will comprise the top sheet according to the invention as front facing in use the incoming radiation, a polymer layer, a layer comprising a wafer-based photovoltaic cell and a back-sheet layer.

Suitable photovoltaic cells may be crystalline silicon cell, CdTe, αSi, micromorph Si or Tandem junction αSi photovoltaic cells.

In certain embodiments of the invention, the photovoltaic cells, the coloured coating layer, and the encapsulant layer may be provided together as an encapsulated photovoltaic element, which can be affixed to the top and back sheet.

Suitable photovoltaic cells and/or photovoltaic elements can be obtained, for example, from several different suppliers, such as China Electric Equipment Group of Nanjing, Uni-Solar, Sharp, USFC, FirstSolar, General Electric, Schott Solar, Evergreen Solar and Global Solar.

Moreover, the person of skill in the art can fabricate encapsulated photovoltaic elements using techniques such as lamination or autoclave processes. The encapsulated photovoltaic elements can be made, for example, using methods disclosed in U.S. Pat. No. 5,273,608, which is hereby incorporated herein by reference.

The top surface of a photovoltaic cell is the surface presenting its photoelectrically-active areas. When installed, the photovoltaic roofing elements of the present invention should be oriented so that the top surface of the photovoltaic cell(s) is illuminated by solar radiation.

The one or more photovoltaic cells have an operating wavelength range. Solar radiation includes light of wavelengths spanning the near UV, the visible, and the near infrared spectra. As used herein, the term “solar radiation,” when used without further elaboration means radiation in the wavelength range of 300 nm to 1500 nm, inclusive. Different photovoltaic elements have different power generation efficiencies with respect to different parts of the solar spectrum. Amorphous doped silicon is most efficient at visible wavelengths, and polycrystalline doped silicon and monocrystalline doped silicon are most efficient at near-infrared wavelengths. As used herein, the operating wavelength range of an encapsulated photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. In certain embodiments of the invention, the operating wavelength range of the encapsulated photovoltaic element falls within the range of about 300 nm to about 1200 nm. For example, for encapsulated photovoltaic elements having photovoltaic cells based on typical amorphous silicon materials the operating wavelength range is between about 375 nm and about 775 nm; for typical polycrystalline silicon materials the operating wavelength range is between about 600 nm and about 1050 nm; and for typical monocrystalline silicon materials the operating wavelength range is between about 425 nm and about 1175 nm.

Photovoltaic cells often have a somewhat metallic appearance, and sometimes have a birefringent colour effect also known as “flop,” i.e. depending on the viewing angle and the illumination angle, the observed colour aspect may change.

To achieve better matching of appearance between the photovoltaic elements and the surrounding substrate upon which they are disposed, in certain embodiments of the invention the back encapsulant layer may be, for example, in the main colour tone that approximates the characteristic dark blue colour of a photovoltaic element.

In certain embodiments of the invention, the coloured top sheet may have a metallic or light-interference effect. Such an effect can help impart a metallic visual effect to the module, so as to better mimic the appearance of the photovoltaic cells.

Back Sheet

The back sheet may advantageously comprise a hard polymer, such as for example a layer of PET, metal, a composite material, or preferably a further glass layer. When thin film photovoltaic cells are employed, for example CIGS and CIS type cells, the photovoltaic module may advantageously comprise a glass top sheet of the present invention, an encapsulant of the present invention, the thin film photovoltaic cell a second encapsulant layer and a rigid support, such as for example glass.

The back sheet or bottom layer material can be, for example, a fluoropolymer, for example ETFE, PFE, FEP, photovoltaicDF or photovoltaicF (“TEDLAR”). The bottom layer material may alternatively be, for example, a polymeric material, including polyester such as PET; or a metallic material, such as steel or aluminium sheet, or preferably, a glass sheet.

The back-sheet layer preferably is pigmented, more preferably to resemble the photovoltaic cells, or it may comprise a so-called white reflector. The presence of pigments in the backsheet is advantageous because it will reflect radiation to the photovoltaic cell and thus improve the efficiency of the cell. This is in particular beneficial where bifacial photovoltaic cells are employed.

Possible backsheet layers comprise fluoropolymer layers. Instead of a fluoropolymer layer a second glass sheet may be provided at the back of the solar cell. This will provide a solar cell which has a glass front and backside. The glass layer for use as backside will preferably have a thickness of less than 3 mm.

The glass layers may be as described above. The use of a glass front and backside is advantageous because it provides a structural strength to the panel such that no separate frame is necessary. The glass backside will also provide an absolute barrier towards water ingress and the like which is advantageous for extending the life time of the panel. The use of the glass layer will make it possible to avoid the use of a back sheet comprising a fluoropolymer.

One or more of the photovoltaic elements described herein above may be combined to a larger element for installation as part of a photovoltaic system for the generation of electric power.

Accordingly, one embodiment of the invention is a photovoltaic architectural system disposed on a building, noise barrier wall, roof deck or the like, comprising one or more photovoltaic roofing elements as described above disposed thereon. The photovoltaic module may comprise cells that are monofacial or bifacial, or both.

Preferably, the sealing elements comprise a polymeric seal with an asymmetric shape to engage in weather sealing relationship with adjacent roofing component positioned horizontally above, and below, respectively.

The seal may be pre-molded and glued, or molded or glued in situ from suitable material, such as for instance (semi)liquid polyurethane, silicones, or a other similar crosslinking material. An alternate attachment method for a seal may utilizes a strip of double-sided tape, the latter including a durable, weather resistant, pressure sensitive adhesive on both its upper and lower surfaces. The shape of the sealing member may be adjusted to the shape of the roof tiles such that a weather-sealing connection is formed.

Preferably, the side elements are shaped and designed to engage a retaining element for retaining the assembly from movement in a direction downward of the building structure.

Preferably, each side frame element is an elongate body comprising at least an outer side portion accommodating for attaching to the retaining element, a panel-engaging portion for accommodating a side edge of the panel.

Preferably, at least one of the side elongate frame element comprises a lateral portion extending from the panel and underneath the a laterally positioned roofing component, preferably a further photovoltaic assembly, and comprising at least one upstanding ridge for engaging in weather sealing relationship with an underside of the laterally positioned roofing component.

Preferably, the side elongate frame element opposite to the side element providing a flashing portion comprises at least one upstanding ridge pointing downwardly, for engaging with a flashing portion of a further assembly or a roofing component in a weather sealing arrangement.

Preferably, the side elements comprise reversible holding means for engaging with the retaining element.

Preferably, the reversible holding means comprises a groves with a keyhole shaped opening such that an assembly may be lifted over a retaining pin, preferably a screw heads extending form the retaining element, after which the assembly can be pulled downwards such that the retaining pin slides into the narrower part of the keyhole shaped opening, thereby securing the assembly to the retaining assembly.

Preferably, the side elements are metal extrusion or folded sheet elements, preferably wherein the metal is selected from aluminium alloys, and/or corrosion resistant steel.

Preferably, the upper elongate frame and sealing element is formed integrally with a seal, or comprises a groove for retaining a flange of a seal, such that an overhanging lip is provided for sealing the upper side of the frame with an underside of a preceding roofing element, thereby protecting the cavity formed between the element and the assembly from weather and UV exposure where the sealing occurs.

Preferably, each sealing element includes a glazing polymeric seal with an asymmetric shape, wherein a lip on a lower portion extends beyond the edge of the lower surface and engages with an upper surface to constrain the lip, for catchment and subsequent direction to external drainage of internal or external moisture.

Preferably, the seal comprises an elastomeric material, preferably a UV stable material selected from a natural or synthetic polymer having elastic properties, such as natural or synthetic rubbers, elastomers silicones, and polyolefins.

Preferably, the seal and the side element are shaped to accommodate the shape of a roofing element adjacent to the assembly.

Preferably, the downward facing seal comprises an overhanging lip portion at the top of a curved face that narrows to a fine edge, to form a compliant seal to the lower surface of a roofing material adjacent in a lateral direction, to effect a seal between the upper surface edge and the lower frame element along this joint to water flowing off the external surface of the panel and onto the next surface while prohibiting ingression between the assembly and the and adjacent roofing component.

Preferably, the photovoltaic panel comprises a lateral zone at the top side that is free from photovoltaic cells, and a photovoltaic zone positioned below the free zone, wherein the zone that is free from photovoltaic cells is designed to be installed underneath an overlapping roofing element, preferably a roof tile or a photovoltaic assembly.

Preferably, the two side elongate elements extend from the top

The present invention also relates to a frameless photovoltaic assembly for incorporation into a tiled roof, comprising two or more assemblies, preferably, wherein assemblies are mounted on a pitched roof with the side walls of adjacent side-by-side assemblies in facing relationship, and secured to the roof by retaining elements engaging the side elements; and optionally, wherein the elements are connected to one another to form a photovoltaic electric grid. The term “frameless” refers to a photovoltaic assembly wherein not all four sides of an assembly are embedded in a frame or four-sided supporting structure that connects and holds in place the solar panel in place.

The present invention also relates to a retaining element for engaging with the side elements of the assembly, the element comprising a supporting portion for supporting the retaining element on a batten of the building structure, and an upper portion for engaging with the side element and/or a roofing component.

The present invention also relates to a retaining element according to claim 18, wherein the retaining elements are formed from a thermoplastic or thermosetting polymeric material, and are provided for attaching the assembly to a batten by holding means, preferably holding screws extending through the blocks and into the batten.

The present invention also relates to a securing element for engaging with the assembly according to the invention, comprising a supporting portion for supporting the assembly and a retaining element for securing to a batten of the building structure, preferably a wind-hook.

The present invention also relates to a photovoltaic panel for use in the assembly. Preferably, the panel comprises a translucent top layer and a bottom layer with photovoltaic cells affixed between the top and bottom layers for providing solar power, and at least one aperture for allowing a passage to wires, cables and/or tubing for attaching a junction element connecting the photovoltaic panel to an electric grid.

Preferably, the photovoltaic panel comprises (a) a top sheet, optionally comprising a pigmented coating layer; (b) a front encapsulant material; (c) an array of photovoltaic elements, (d) a layer of electric connectors; (e) a back encapsulant material; (f) a backsheet, and (g) at least one connector for connecting the panel to an electric grid.

The present invention also relates to a roof comprising an assembly according to the invention, and at least one electrical convertor for converting the photovoltaic electricity to electricity that can be fed into a residential electricity grid.

The present invention also relates to a kit of parts comprising at least one assembly according to the description, and at least one retaining system.

The photovoltaic elements of the photovoltaic roofing elements are desirably connected to an electrical system, either in series, in parallel, or in series-parallel, as would be recognized by the skilled artisan. There can be one or more layers of material, such as underlayment, between the roof deck and the photovoltaic roofing elements of the present invention.

The photovoltaic roofing elements of the present invention can be installed on an existing building or roof; in such embodiments, there may be one or more layers of “dummy” i.e., non-photovoltaic cladding elements that have the same built-up, but are void of photovoltaic cells, but provide essentially the same optical effect and protection from the environment, and the photovoltaic elements according to the present invention.

Photovoltaic elements of the present invention can be fabricated using many techniques familiar to the skilled artisan. It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

In contrast to many known photovoltaic roof constructions, the construction as claimed in the invention does not require two separate frame envelopes. Rather weather protection and energy recovery are combined into a single panel, specifically in the assembly arranged as claimed in this specification.

In this case panels (9a) are called “directly adjacent” which overlap over a certain length of the edge region. Panels are called “indirectly adjacent” which are typically next to one another at the same height with respect to the line of slope, but do not overlap.

It is desirable for the roof of a building to exhibit a uniform impression. The panel system according to the invention therefore may include not only panels with, but also those without photovoltaic cells, and roof tiles.

The panels with photovoltaic cells may be installed at sites of the building exposed to the sun and the panels without photovoltaic cells, or roofing tiles on the side facing away from the sun.

Furthermore, in the system there are also tiles, or panels which are free of photovoltaic cells for the edge termination of the roof. These panels may be of any shape, for example triangular. The shape of these panels can arise by division of the regular panel shape parallel to a diagonal line into two unequal parts.

The panel shape is generally a rectangular shape, but square or other shapes are also possible. As is apparent from the aforementioned explanations, the system is not however limited to these panels.

### DETAILED DESCRIPTION OF THE DRAWINGS

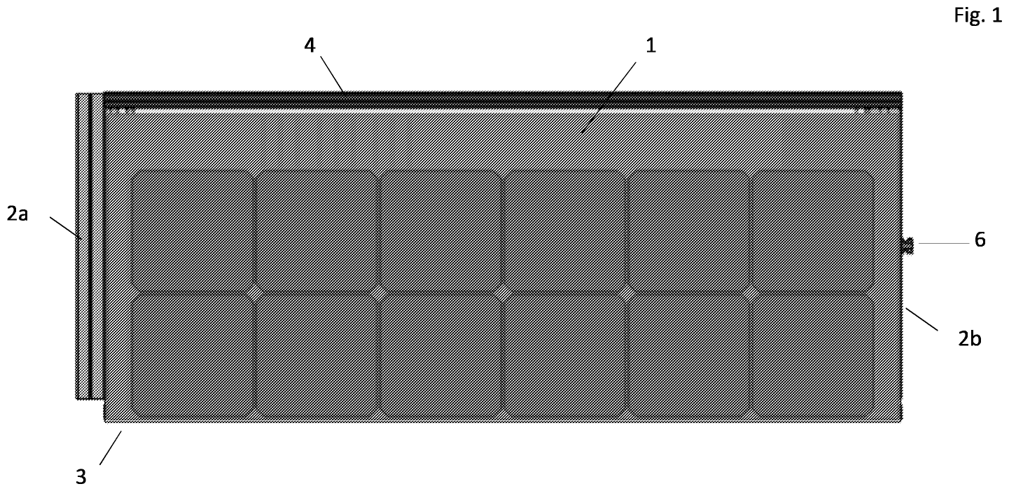

FIG. 1 is a perspective view from above the assembly (1), wherein a side element 2a extends from the underside of a photovoltaic panel, whereas a second side element (2a) is not visible; a elongate sealing elements (3, not shown as on the underside)) and (4) are bonded to the panel; and an electrical adapter is (6) extends from a side of the assembly (1).

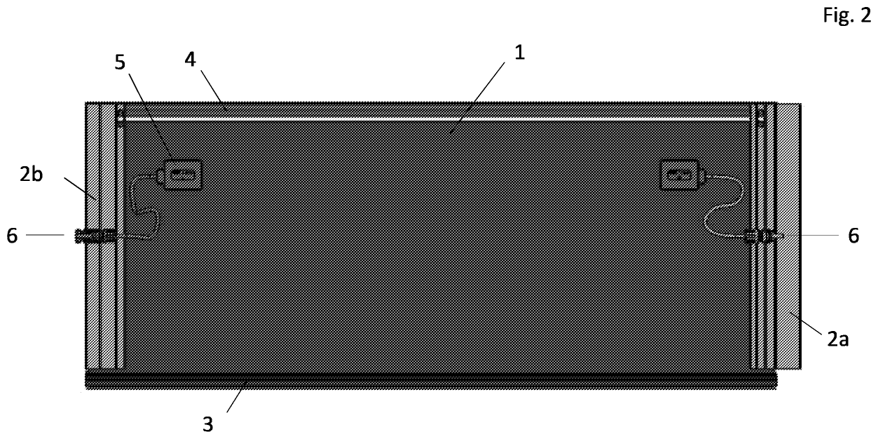

FIG. 2 is a perspective view showing the underside of the panel, showing side elements (2a) and (2b), junction boxes (5) and electrical connectors (6), and horizontal sealing panels (3) and (4), wherein side members and elongate sealing member 4 extend at the upper side of the panel.

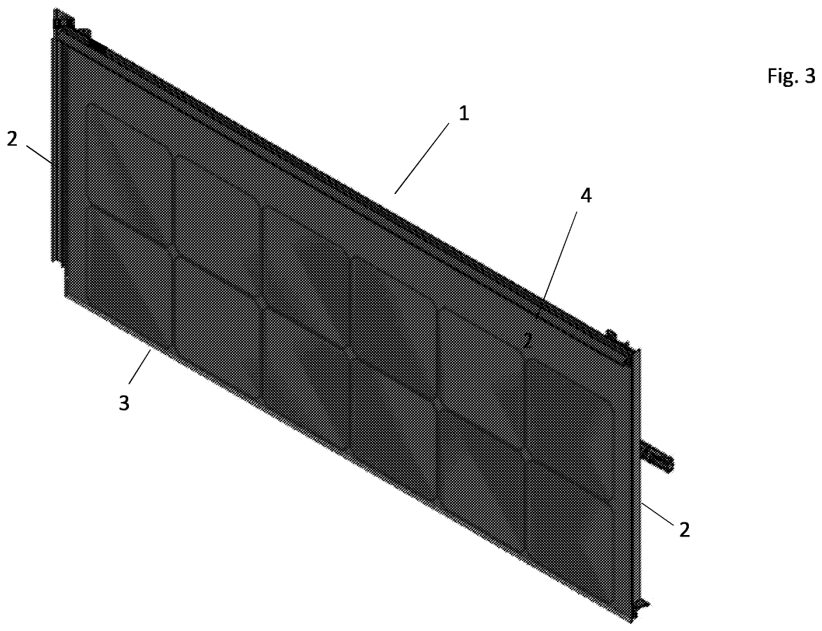

FIG. 3 is a perspective view showing the assembly from an about 45° angle.

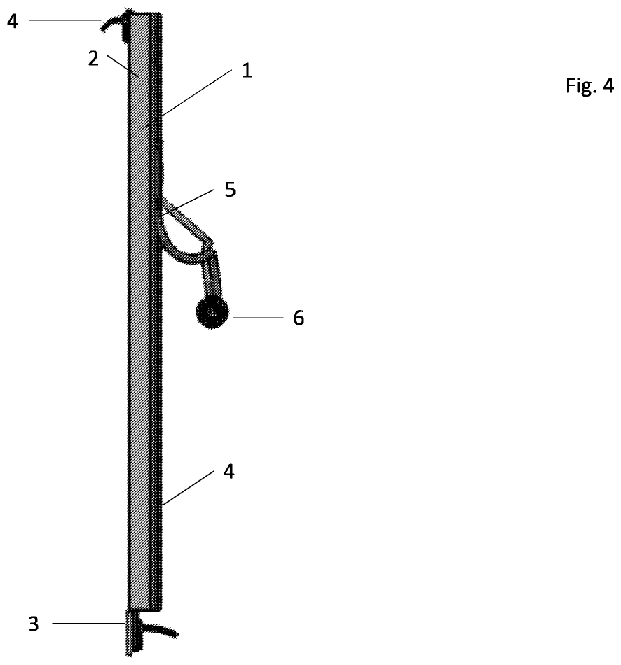

FIG. 4 is a side perspective view from the side of a panel; showing a side element (2), junction box (5) electrical connector (6), and lower element (3) with a right-facing sealing lip, and an upper sealing element (4) showing a left-facing sealing lip. In use the left-facing sealing lip forms a weather-sealing to an upper roofing component (9, not shown), whereas the right-facing sealing lip forms a weather-sealing to a lower roofing component (9, not shown).

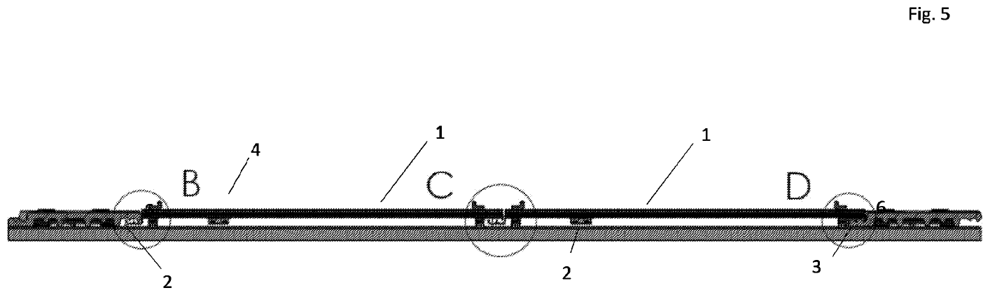

FIG. 5 is a cut-away perspective view from the side of two assemblies connecting centrally to one another, and two roof tiles to the left and right, showing a fully integrated and flush photovoltaic assembly. The extending side member 2 si shown as B to interlock and forms a weather-sealing connection with the left-hand sided underside of the adjacent tile; the side elements 2a and 2b shown as C interact and form a weather-sealing connection between two assemblies, and an extending side of a roof tile interlocks and forms a weather-sealing connection D with the second assembly on the righthand side.

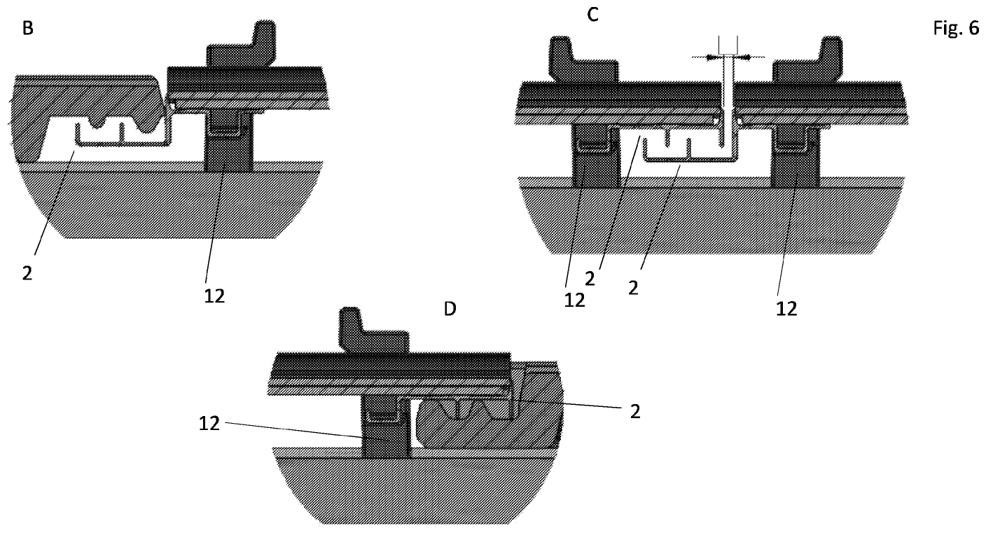

FIG. 6 is a perspective enlarged view of connections B, C and D, also showing the retaining brackets 12 which retains the different components, as well as spacing them suitably.

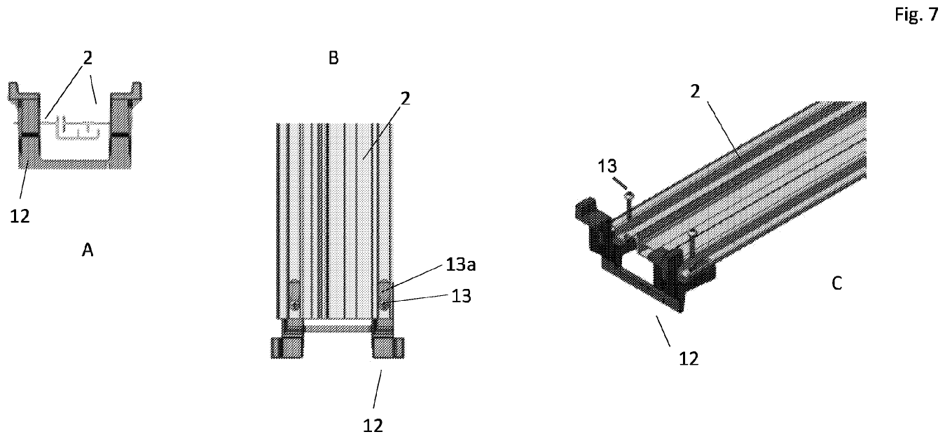

FIG. 7 shows side (A) and perspective views (B) and (C) of preferred embodiments of the side elements, when held in the retaining brackets (12), showing screws (13) for connecting the retaining brackets 12 to a batten (not shown), and keyhole shaped openings (13a) in the side elements (2) that allows removal and fixing again while retaining the screws (13) in place).

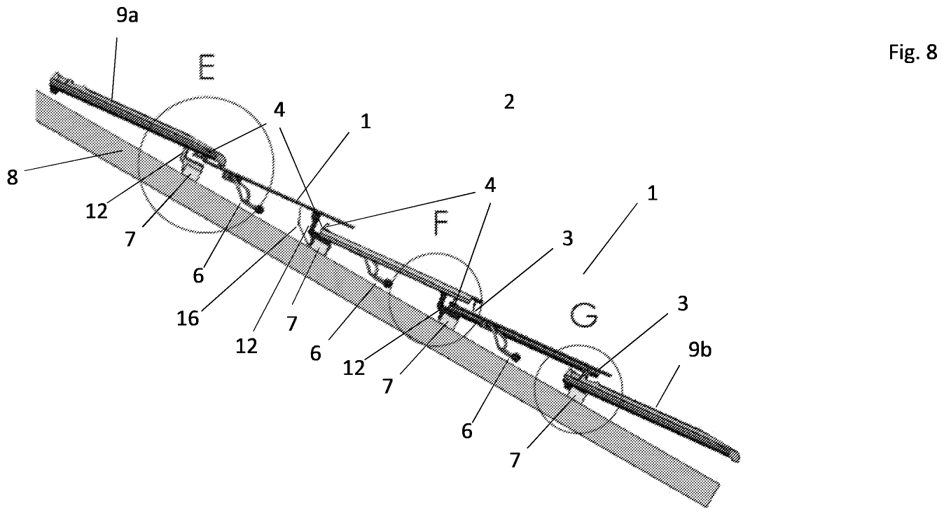

FIG. 8 is a cut-away perspective view from the side showing three different assemblies according to the invention, placed between two roof tiles in a sloping roof comprising battens and a roof construction. Herein, each of the components overlaps at least a portion of a lower component in scale-like manner. The assemblies and roof tiles are shown with integral projections for positioning the assembly relative to roof battens. Herein, in FIG. 8 E, an upper roof tile (9a) overlaps with a first assembly (1), wherein a bracket (12) is fixed to a batten (7), which in turn resides on the under-roof construction (8). The bracket positions the lower portion of the roof tile such that the upper portion of assembly 1, the sealing element 4 are in a weather-sealing position with the underside of the roof tile, keeping wind, water and snow from ingress into the space below the roof tile. The lower end of the assembly 1 rests on another retaining bracket 12, which is also affixed to the next lower batten (7). Wind-hook 16 is depicted, which retains assembly connected to the lower batten (7). Under F, a further assembly 1 is positioned on the bracket 12 at the upper end, forming an upper weather sealing connection with upper sealing member (4), as well as forming a lower weather sealing connection with upper side of the next adjacent assembly below. Under G, a further assembly 1 is positioned on the bracket 12 at the upper end, with a lower sealing member 3 forming a weather sealing connection with upper side of the adjacent roof tile. Additionally, foam or elastomer sealing strips 10 may be employed in addition to, or as lower sealing member 3, to enhance the fit, and weather sealing connection with different kinds of roof components, such as different roof tiles.

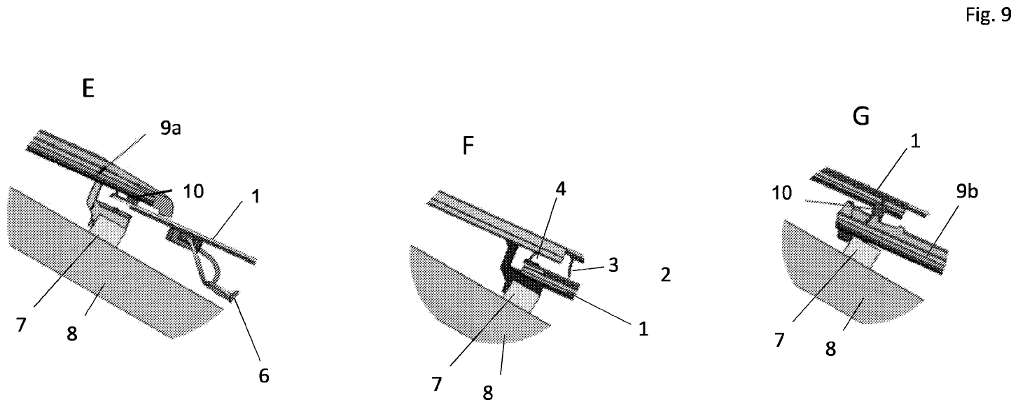

FIG. 9 E to G are detailed enlargements of the situations of Figures E to G, showing different variants of fixing the assemblies. In E, the top of the assembly is bonded to the underside of the roof tile 9a with a sealing strip 10 forming sealing element 4, and does not need to rest on the bracket 12. F shows the interconnection between bracket 12, assemblies, and the upper and lower sealing members. G finally, shows the inverse to, namely the assembly overlapping with a roof tile (9b), and affixed to the roof tile via sealing member 10.

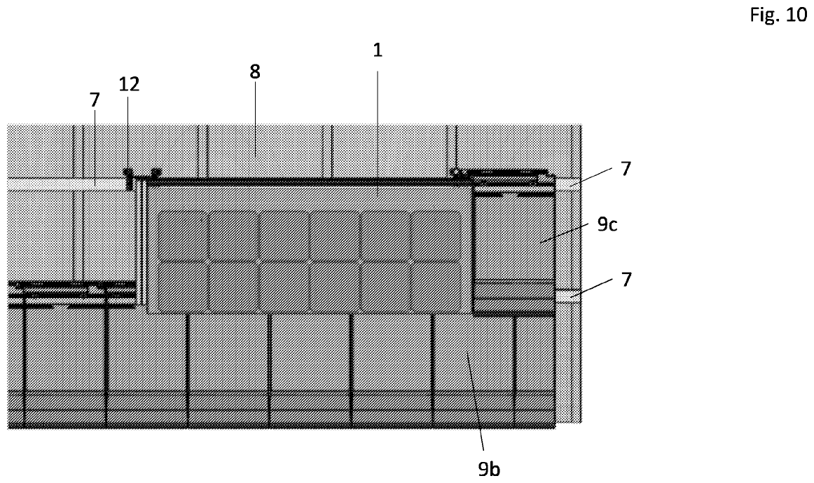

FIG. 10 is a perspective view of an assembly according to the invention, showing an assembly installed on a tiled roof, showing the battens 7 and the retaining bracket 12, and adjacent tiles 9c and 9b, respectively.

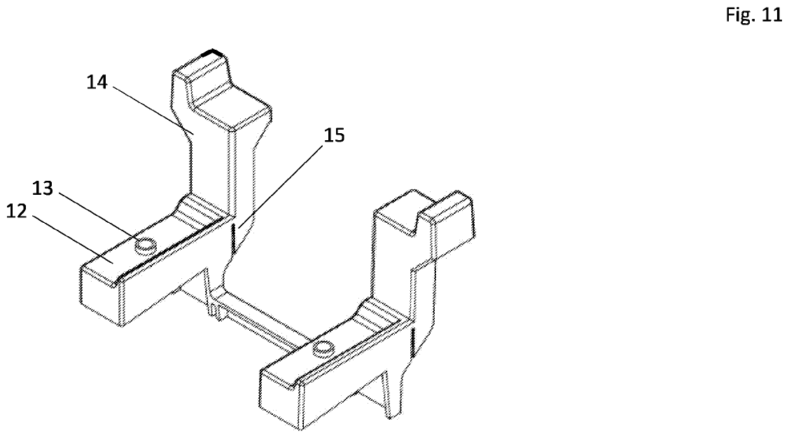

FIG. 11 is a perspective view showing a retainer bracket or element, with retaining opening 13, upper section 14, which may be snapped off if used under a roof tile, if plied around pre-set break section 15.

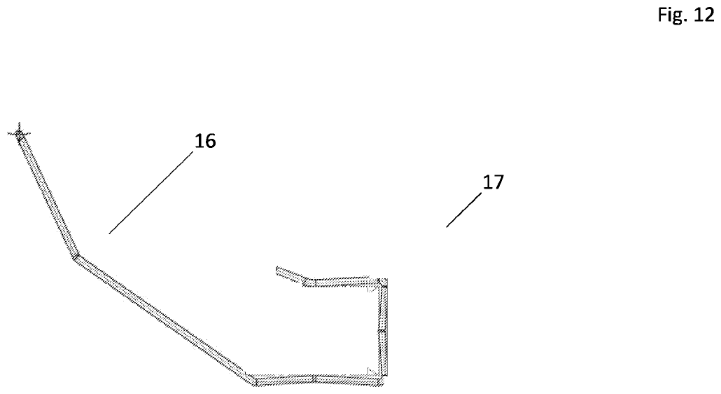

FIG. 12 is a side view showing a wind hook (16), showing the retaining portion for a panel (16), and a portion for attaching to a batten (17).

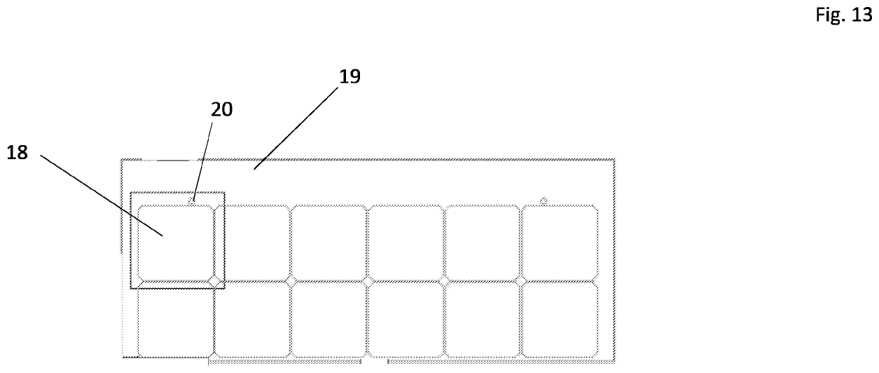

FIG. 13 is a perspective view showing a photovoltaic panel according to the invention, with a free zone 19, and a photovoltaic zone formed from two rows of photovoltaic cells 18, and showing 3 openings in the lower panel for electric connectors.

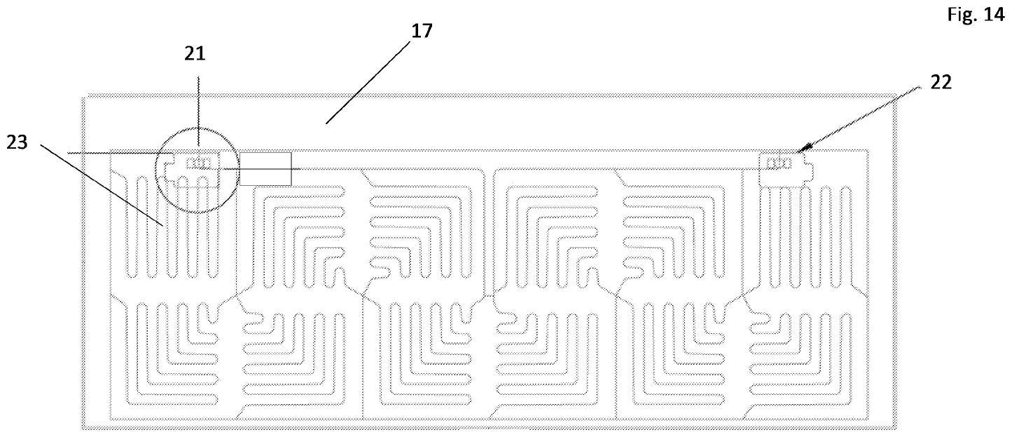

FIG. 14 is a perspective view of the photovoltaic panel, showing conductors ribbons 23 inside the panel, and outlining the entry opening 21 for the junction box 22.

The invention also comprises a kit for preparing a building envelope which is suitable for use of photovoltaic energy. The kit includes the aforementioned rectangular weatherproof panels which can be installed with respect to the line of slope in a horizontal position with scale-like mutual overlapping. Furthermore the kit includes fasteners to connect the panels to a bearing structure on one corner region at a time which lies underneath with respect to the line of slope. Furthermore the kit also comprises sealing elements to be arranged at the indicated corner region of the panel and to close the gap between the panels which are located transversely to the main direction at the same height.

A roof, or more generally, building envelop according to the invention and the kit for preparing it can be regarded as a part of an overall system for use of photovoltaic energy. Further aspects of the invention are set out in the following description and in the claims.

1. A frameless photovoltaic assembly for incorporation into a tiled roof, the assembly comprising:
(i) a photovoltaic panel comprising a transparent top sheet and a backsheet, and one or more photovoltaic cells positioned between the top and backsheet;
(ii) two side elongate elements extending vertically along the sides of the panel;
(iii) an upper elongate sealing element extending in a horizontal direction, and attached to an upper end of the side elongate elements and above the photovoltaic panel,
(iv) a lower elongate sealing element extending horizontal direction and attached to the panel in horizontal direction on the underside of the panel, but preferably not attached to the elongate side elements; wherein at least one of the side elongate frame element extends laterally to form a flashing portion that substantially interlinks with the underside of a laterally positioned roofing component.

2. The assembly according to claim 1, wherein the sealing elements comprise a polymeric seal with an asymmetric shape to engage in weather sealing relationship with adjacent roofing component positioned horizontally above, and below, respectively.

3. The assembly according to claim 1 or claim 2, wherein the sealing elements are bonded to the upper or lower surface of the photovoltaic panel, respectively.

4. The assembly according to any one of the previous claims, wherein the side elements are shaped and designed to engage a retaining element for retaining the assembly from movement in a direction downward of the building structure.

5. The assembly according to claim 4, wherein each side frame element is an elongate body comprising at least an outer side portion accommodating for attaching to the retaining element, a panel-engaging portion for accommodating a side edge of the panel.

6. The assembly according to any one of the previous claims, wherein the at least one of the side elongate frame element comprises a lateral portion extending from the panel and underneath a laterally positioned roofing component, prefearbly a further photovoltaic assembly, and comprising at least one upstanding ridge for engaging in weather sealing relationship with an underside of the laterally positioned roofing component.

7. The assembly according to any one of the previous claims, wherein the side elongate frame element opposite to the side element providing a flashing portion comprises at least one upstanding ridge pointing downwardly, for engaging with a flashing portion of a further assembly or a roofing component in a weather-sealing arrangement.

8. The assembly according to any one of the previous claims, wherein the side elements comprise reversible holding means for engaging with the retaining element.

9. The assembly according to claim 8, wherein the reversible holding means comprises a groves with a keyhole shaped opening such that an assembly may be lifted over a retaining pin, preferably a screw heads extending form the retaining element, after which the assembly can be pulled downwards such that the retaining pin slides into the narrower part of the keyhole shaped opening, thereby securing the assembly to the retaining assembly.

10. The assembly according to any one of the previous claims, wherein the side elements are metal extrusion or folded sheet elements, preferably wherein the metal is selected from aluminium alloys, and/or corrosion resistant steel.

11. The assembly according to any one of the previous claims, wherein the upper elongate frame and sealing element is formed integrally with a seal, or comprises a groove for retaining a flange of a seal, such that an overhanging lip is provided for sealing the upper side of the frame with an underside of a preceding roofing element, thereby protecting the cavity formed between the element and the assembly from weather and UV exposure where the sealing occurs.

12. The assembly according to any one of the previous claims, wherein each sealing element includes a glazing polymeric seal with an asymmetric shape, wherein a lip on a lower portion extends beyond the edge of the lower surface and engages with an upper surface to constrain the lip, for catchment and subsequent direction to external drainage of internal or external moisture.

13. The assembly according to any one of the previous claims, wherein the seal comprises an elastomeric material, preferably a UV stable material selected from a natural or synthetic polymer having elastic properties, such as natural or synthetic rubbers, elastomers silicones, and polyolefins.

14. The assembly according to claim 13, wherein the seal and the side element is shaped to accommodate the shape of a roofing element adjacent to the assembly.

15. The assembly according to any one of claims 1 to 14, wherein the downward facing seal comprises an overhanging lip portion at the top of a curved face that narrows to a fine edge, to form a compliant seal to the lower surface of a roofing material adjacent in a lateral direction, to effect a seal between the upper surface edge and the lower frame element along this joint to water flowing off the external surface of the panel and onto the next surface while prohibiting ingression between the assembly and the and adjacent roofing component.

16. The assembly according to any one of claims 1 to 15, wherein the photovoltaic panel comprises a lateral zone at the top side that is free from photovoltaic cells, and a photovoltaic zone positioned below the free zone, wherein the zone that is free from photovoltaic cells is designed to be installed underneath an overlapping roofing element, preferably a roof tile or a photovoltaic assembly.

17. The assembly according to claim 16, wherein the two side elongate elements extend from the top edge of the photovoltaic panel for at least the length of a neighbouring roof component, to the lower sealing element, and wherein the lower sealing element is positioned to overlap with at least a portion of a lower positioned roof component to form a scale-like weather-sealing arrangement with an upper surface of the lower positioned roof component.

18. A photovoltaic building assembly for incorporation into a tiled roof, comprising two or more assemblies according to any one of claims 1 to 17 arranged in a horizontally and/or vertically adjacent weather-sealing arrangement.

19. A building assembly according to claim 18, wherein the photovoltaic assemblies are mounted on a pitched roof with the side walls of adjacent side-by-side assemblies in a facing relationship such that a laterally extending side element interlinks with an adjacent side element, thereby forming a weather-sealing flashing portion, wherein the assemblies are each secured to the roof construction by retaining elements engaging the side elements.

20. A building assembly according to claim 18 or claim 19, wherein the assemblies are further connected on the downward facing surface to form a photovoltaic electric grid.

21. A retaining element for engaging with the side elements of the assembly according to any one of claims 1 to 17, the element comprising a supporting portion for supporting the retaining element on a batten of the building structure, and an upper portion for engaging with the side element and/or a roofing component.

22. A retaining element according to claim 21, wherein the retaining elements are formed from a thermoplastic or thermosetting polymeric material, and are provided for attaching the assembly to a batten by holding means, preferably holding screws, extending through the blocks and into the batten.

23. A securing element for engaging with the assembly according to any one of claims 1 to 17, comprising a supporting portion for supporting the assembly and a retaining element for securing to a batten of the building structure, preferably in the shape of a metal band forming a wind-hook fastening a lower portion of the photovoltaic assembly to a batten of the roof construction.

24. The assembly according to any one of claims 1 to 17, wherein the panel comprises a translucent top layer and a bottom layer with photovoltaic cells affixed between the top and bottom layers for providing solar power, and at least one aperture for allowing a passage to wires, cables and/or tubing for attaching a junction element connecting the photovoltaic panel to an electric grid.

25. An assembly, according to any one of claims 1 to 17, wherein the photovoltaic panel comprises (a) a top sheet, optionally comprising a pigmented coating layer; (b) a front encapsulant material; (c) an array of photovoltaic elements, (d) a layer of electric connectors; (e) a back encapsulant material; (f) a backsheet, and (g) at least one connector for connecting the panel to an electric grid.

26. A roof comprising an assembly according to any one of claims 1 to 17, and at least one electrical convertor for converting the photovoltaic electricity to electricity that can be fed into a residential electricity grid.

27. A kit of parts comprising at least one assembly according to any one of claims 1 to 17, and at least one retaining system according to any one of claim 21 or 22.

28. A photovoltaic panel comprising a transparent top sheet and a backsheet, and one or more photovoltaic cells positioned between the top and backsheet, for use in the photovoltaic assembly according to any one of claims 1 to 17.
